(19) United States
(12) Patent Application Publication
(10) Pub. No.: US 2019/0038991 A1
(43) Pub. Date: Feb. 7, 2019

(54) SPINNING DEVICE USING MAGNETIC INTERACTIONS

(71) Applicant: SETON SCHIRAGA, Alameda, CA (US)

(72) Inventor: SETON SCHIRAGA, Alameda, CA (US)

(21) Appl. No.: 15/670,917

(22) Filed: Aug. 7, 2017

(51) Int. Cl. A63H 33/26; H01F 7/02; H01L 33/00

(52) U.S. Cl. CPC A63H 33/26; G01D 5/00; H01L 33/0045; H01F 7/02

(57) ABSTRACT

A spinning device includes a bearing portion and a magnet portion with magnets disposed on facing end surfaces of each. The magnets on each of the end surfaces can have alternating poles facing outward, causing a detented motion between the two portions as they are rotated along their longitudinal axes. The magnet portion can include a magnet that is mutually attracted to ferrous surfaces at either end of a section of a copper tube. Lenz force between the copper and the moving magnet damps the magnet's motion and provides a smooth feel to the user. The bearing portion includes bearing(s) which accept a protruding shaft from the magnet portion. In addition to a spinning, detented motion, the user can also toggle the protruding shaft from extending out of opposite ends of the device. The device may include features to create an interaction between the device and an external computing device.

### BACKGROUND OF THE INVENTION

### 1. Field of the Invention

One or more embodiments of the invention relates generally to magnetically interacting spinning devices. More particularly, the invention relates to a fidget toy allowing a user to turn and/or click components thereof with magnetic interactions.

### 2. Description of Prior Art and Related Information

The following background information may present examples of specific aspects of the prior art (e.g., without limitation, approaches, facts, or common wisdom) that, while expected to be helpful to further educate the reader as to additional aspects of the prior art, is not to be construed as limiting the present invention, or any embodiments thereof, to anything stated or implied therein or inferred thereupon.

“Fidgeting” consists of actions that are conducted by certain persons as a means to release internal tension so as to allow the person to better concentrate, focus and complete tasks that would be problematic without the ability to fidget. Many fidgeting actions result in motions and noise that may be self-destructive and/or disruptive to others. Accordingly, fidgeting, while beneficial to the user, is often discouraged in schools and other settings where other people are present.

Current fidget spinning devices typically include a central bearing configured to be held, for example, between a user's thumb and finger, and a plurality of arms extending from the central bearing, the arms providing weight to give the spinner sufficient angular momentum to spin for a period of time.

Most conventional fidget spinners are single action devices. However, many “fidgeters” utilize multiple methods of fidgeting. For example, a person may like to twist a pen end on and off while also clicking the pen. Moreover, conventional fidget spinners are aimed at the fidgeting, without providing additional functions or features to the user.

In view of the foregoing, there is a need for an improved spinning device.

### SUMMARY OF THE INVENTION

Embodiments of the present invention provide a device comprising at least one of a spinning device and a toggle device, wherein the spinning device comprises a first wheel having a first plurality of magnets disposed about an outer circumference of a first end, the first plurality of magnets arranged with poles facing parallel to a longitudinal axis of the spinning device, and a second wheel having a second plurality of magnets disposed about an outer circumference of a first end, the second plurality of magnets arranged with poles facing parallel to a longitudinal axis of the spinning device, the first end of the first wheel disposed adjacent against the first end of the second wheel, the first and second wheels independently rotatable about the longitudinal axis of the spinning device; and the toggle device comprises a toggle mechanism extending along the longitudinal axis of the spinning device, the toggle mechanism movable between a first position, with a visible portion of the toggle mechanism being visible out of a second end of the first wheel, and a second position, with the visible portion of the toggle mechanism being visible out of a second end of the second wheel.

Embodiments of the present invention further provide a spinning device comprising a first wheel having a first plurality of magnets disposed about an outer circumference of a first end, the first plurality of magnets arranged with poles facing parallel to a longitudinal axis of the spinning device; a second wheel having a second plurality of magnets disposed about an outer circumference of a first end, the second plurality of magnets arranged with poles facing parallel to a longitudinal axis of the spinning device, the first end of the first wheel disposed adjacent against the first end of the second wheel, the first and second wheels independently rotatable about the longitudinal axis of the spinning device; and an input device extending from at least one of the second end of the first wheel and the second end of the second wheel.

Embodiments of the present invention also provide a spinning device comprising a first wheel having a first number of magnets disposed about an outer circumference of a first end, the first plurality of magnets arranged with like poles facing parallel to a longitudinal axis of the spinning device; a floating spinner having a second number of magnets disposed about a bottom surface thereof, the second number of magnets arranged with like poles facing downward along and parallel to a longitudinal axis of the spinning device, the floating spinner fitting partially in the first wheel, the floating spinner being independently rotatable about the longitudinal axis of the spinning device, wherein the magnets of the first wheel repel the magnets of the floating spinner.

In some embodiments, the spinning device includes at least one rotational position sensor operable to detect a relative rotational position of the first wheel relative to the second wheel.

In some embodiments, the spinning device includes at least one linear position sensor operable to detect a distance between the first end of the first wheel and the first end of the second wheel.

In some embodiments, the spinning device includes at least one linear position sensor operable to detect a position of the toggle mechanism.

In some embodiments, the spinning device includes a controller receiving inputs from one or more position sensors disposed in the spinning device and a wireless communication module for sending signals from the controller to an external computing device.

In some embodiments, the spinning device includes a laser diode configured to emit a laser signal from the spinning device.

In some embodiments, the spinning device includes a plurality of push buttons disposed about an external surface of at least one of the first wheel and the second wheel.

These and other features, aspects and advantages of the present invention will become better understood with reference to the following drawings, description and claims.

### BRIEF DESCRIPTION OF THE DRAWINGS

Some embodiments of the present invention are illustrated as an example and are not limited by the figures of the accompanying drawings, in which like references may indicate similar elements.

FIG. 1 is a side view of a spinning device according to an exemplary embodiment of the present invention;

FIG. 2 is a perspective view of the spinning device of FIG. 1;

FIG. 3 is a cross-sectional view of the spinning device of FIG. 1;

FIG. 4 is an exploded perspective view of the spinning device of FIG. 1;

FIG. 5 is a perspective view of a portion of the spinning device of FIG. 1 in use with a spinning wheel attachment, according to an exemplary embodiment of the present invention;

FIG. 6 is an exploded perspective view of the spinning device of FIG. 5;

FIG. 6A is a bottom view of the spinning wheel attachment of the spinning device of FIG. 5;

FIG. 6B is a top view of a bearing portion, supporting the spinning wheel attachment, of the spinning device of FIG. 5;

FIG. 7 is a detailed cross-sectional view of a spinning device having a rotational position sensor according to an exemplary embodiment of the present invention;

FIG. 8 is a detailed cross-sectional view of a spinning device having a linear position sensor for determining a linear position between the two components thereof, according to an exemplary embodiment of the present invention;

FIG. 9 is a detailed cross-sectional view of a spinning device having a linear position sensor for determining a linear position of an internal toggle mechanism thereof, according to an exemplary embodiment of the present invention;

FIG. 10 is a block diagram illustrating use of a spinning device to send data to an external computing device, according to an exemplary embodiment of the present invention;

FIG. 11 is a side view of a spinning device illustrating relative rotation thereof for controlling an external computing device, according to an exemplary embodiment of the present invention;

FIG. 12 is a detailed cross-sectional view of an end portion of a spinning device, where a longitudinally extending toggle is replaced by a push button, according to an exemplary embodiment of the present invention;

FIG. 13A is a side view of a spinning device, in a compact configuration, illustrating relative rotation thereof, according to an exemplary embodiment of the present invention;

FIG. 13B is a side view of a spinning device, in an extended configuration, illustrating relative motion thereof, according to an exemplary embodiment of the present invention

FIG. 14 is a side view of a spinning device having a laser pointer feature, according to an exemplary embodiment of the present invention;

FIG. 15 is a schematic perspective view of a spinning device that can use inertial measurements to create, for example, a pointer interacting with a display screen, according to an exemplary embodiment of the present invention;

FIG. 16 is a detailed end view of a spinning device having a non-compliant joystick input configured into one or both ends thereof, according to an exemplary embodiment of the present invention;

FIG. 17 is a detailed end view of a spinning device having a three-axis compliant proportional joystick input configured into one or both ends thereof, according to an exemplary embodiment of the present invention; and

FIG. 18 is a side view of a spinning device having a plurality of push buttons disposed about an outer periphery of each of the halves thereof, according to an exemplary embodiment of the present invention.

Unless otherwise indicated illustrations in the figures are not necessarily drawn to scale. The invention and its various embodiments can now be better understood by turning to the following detailed description wherein illustrated embodiments are described. It is to be expressly understood that the illustrated embodiments are set forth as examples and not by way of limitations on the invention as ultimately defined in the claims.

### DETAILED DESCRIPTION OF THE PREFERRED EMBODIMENTS AND BEST MODE OF INVENTION

The terminology used herein is for the purpose of describing particular embodiments only and is not intended to be limiting of the invention. As used herein, the term “and/or” includes any and all combinations of one or more of the associated listed items. As used herein, the singular forms “a,” “an,” and “the” are intended to include the plural forms as well as the singular forms, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

Unless otherwise defined, all terms (including technical and scientific terms) used herein have the same meaning as commonly understood by one having ordinary skill in the art to which this invention belongs. It will be further understood that terms, such as those defined in commonly used dictionaries, should be interpreted as having a meaning that is consistent with their meaning in the context of the relevant art and the present disclosure and will not be interpreted in an idealized or overly formal sense unless expressly so defined herein.

In describing the invention, it will be understood that a number of techniques and steps are disclosed. Each of these has individual benefit and each can also be used in conjunction with one or more, or in some cases all, of the other disclosed techniques. Accordingly, for the sake of clarity, this description will refrain from repeating every possible combination of the individual steps in an unnecessary fashion. Nevertheless, the specification and claims should be read with the understanding that such combinations are entirely within the scope of the invention and the claims.

In the following description, for purposes of explanation, numerous specific details are set forth in order to provide a thorough understanding of the present invention. It will be evident, however, to one skilled in the art that the present invention may be practiced without these specific details.

The present disclosure is to be considered as an exemplification of the invention, and is not intended to limit the invention to the specific embodiments illustrated by the figures or description below.

As is well known to those skilled in the art, many careful considerations and compromises typically must be made when designing for the optimal configuration of a commercial implementation of any system, and in particular, the embodiments of the present invention. A commercial implementation in accordance with the spirit and teachings of the present invention may be configured according to the needs of the particular application, whereby any aspect(s), feature(s), function(s), result(s), component(s), approach(es), or step(s) of the teachings related to any described embodiment of the present invention may be suitably omitted, included, adapted, mixed and matched, or improved and/or optimized by those skilled in the art, using their average skills and known techniques, to achieve the desired implementation that addresses the needs of the particular application.

Broadly, embodiments of the present invention provide a spinning device having two halves—a bearing end and a magnet end, where both halves may include magnets disposed on facing end surfaces thereof. The magnets on each of the end surfaces can have alternating poles facing outward and toward each other, causing a detented motion between the two halves as they are rotated along their longitudinal axes. The magnet end can include a magnet that is mutually attracted to ferrous surfaces at either end of a section of a tube, such as a copper tube. Lenz force between the copper and the moving magnet damps the magnet's speed and provides a smooth feel to the user. The bearing end includes bearings which accepts a protruding shaft from the magnet end. In addition to a spinning, detented motion, the user can also toggle the protruding shaft from extending out of opposite ends of the device. The device may include features to create an interaction between the device and an external computing device. The magnet end may be changed with various spinning devices.

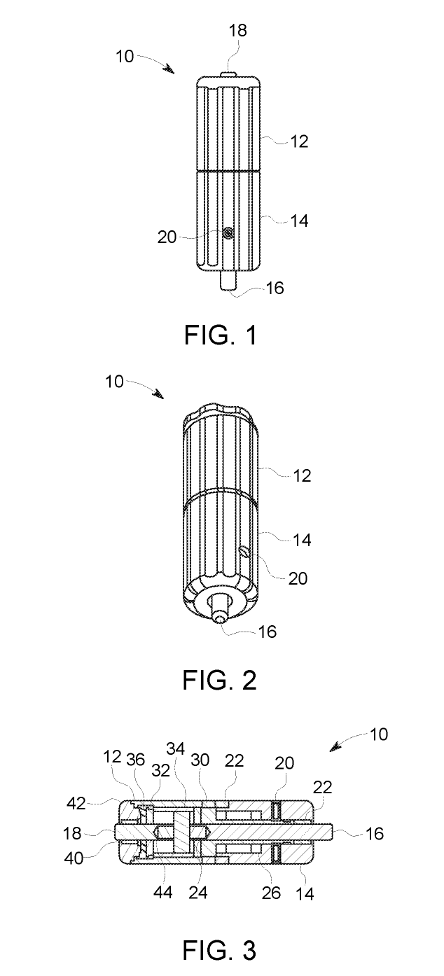

Referring to FIGS. 1 through 4, a spinning device 10, or simply device 10, can include a magnet portion 12 and a bearing portion 14 that, together, may form a generally cylindrical object where the portions 12, 14 may be rotated relative to each other, as described in greater detail below. A magnet end toggle 18 may extend out an end of the magnet portion 12 and a bearing end toggle 16 may extend out an end of the bearing end 14, where the toggles 16, 18 may be integral or interconnected so that a user can depress bearing end toggle 16 which extends from the bearing end 14, as shown in FIG. 1, causing bearing end toggle 16 to move inward and further causing the magnet end toggle 18 to protrude. The user may alternate which end of the toggle 16, 18 protrudes from the device 10.

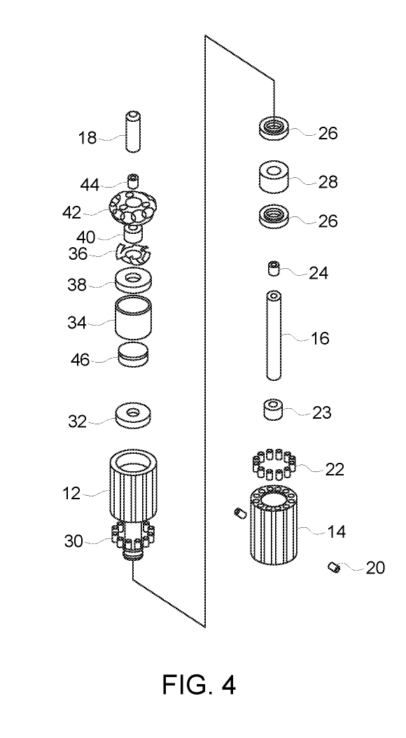

The toggle feature of the device 10 may be constructed, for example, as shown in FIG. 4, where the magnet end toggle 18 may attach, via first attachment magnet 44, to a damping magnet 46. The damping magnet 46 may be disposed inside of a conductive metal tube 34, such as a copper tube 34, with the magnet end toggle 18 passing through a first compliant member 38, such as a spring or a sealing washer, disposed on a first end of the conducive metal tube 34. The conductive metal tube 34 may be formed from a high conductivity material, such as silver, gold, aluminum, super conductors, or the like.

The magnet end toggle 18 may extend form the magnet portion 12 through an endcap 42, which may help keep the magnet end toggle 18 centered in the magnet portion 12. The magnet end toggle 18 may also pass through a sleeve, such as a sleeve, such as a polytetrafluoroethylene (PTFE) sleeve 40, as well as a finger disc spring 36 before passing through the first compliant member 38.

A second compliant member 32, such as a spring or a sealing washer, may be disposed on an opposite side of the conductive metal tube 34 and bearing end toggle 16 may pass from the bearing end 14, through the second compliant member 32 and may connect to magnet 46 via a second attachment magnet 24. Thus, magnet end toggle 18 is connected linearly with the bearing end toggle 16, with the magnet 46 disposed there between.

The bearing portion 14 can include a sleeve, such as a PFTE sleeve 22 for supporting the bearing end toggle 16. One or more bushings or bearings 26, generically referred to as bearings 26, may be disposed within the bearing end for permitting rotation of the bearing portion 14 relative to the magnet portion 12. In some embodiments, two bearings 26 may be disposed on opposite ends of a bearing spacer 28.

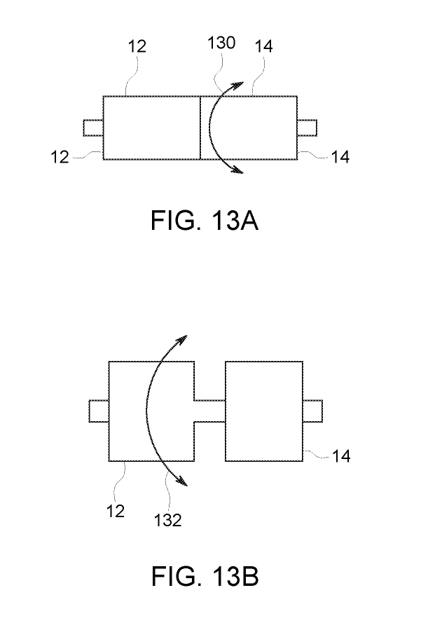

An extension portion 11 of the magnet portion 12 may extend into the bearing portion 14. A retention mechanism may be used to keep the magnet portion 12 and the bearing portion 14 in at least two distinct positions—a close position, as shown in FIG. 1, and a spaced position as shown in FIG. 13B, for example. In some embodiments, the retention mechanism may include one or more spring plungers 20 extending into an interior of the bearing portion 14 so that detents 13 (see FIG. 8) formed in magnet end 12 may be engaged by the spring plungers 20 when the device 10 is assembled.

A plurality of magnet portion magnets 30 may be disposed in one face of the magnet portion 12. This face may be the face from which the extension portion 11 extends, or, in other words, the face that faces the bearing portion 14. A plurality of bearing portion magnets 22 may be disposed in one face of the bearing portion 14. This face may be the surface that faces the magnet portion 12. Thus, the magnet portion magnets 30 and the bearing portion magnets 22 may face each other with the device 10 is assembled as shown in FIG. 1. In some embodiments, the poles of the magnets 30, 22 may alternate so that the turning of the magnet portion 12 relative to the bearing portion 14 may feel detented. In other words, the user may turn the portions 12, 14 relative to each other a set number of degrees, where this set number of degrees is 360 divided by the number of magnets 30, for example, so that after turning the portions 12, 14 relative to each other that set number of degrees, the magnets will be aligned end to end, with opposite poles attracting each other. Continued turning will result in an opposing force to separate the magnets (over a number of degrees half the above calculated set number of degrees), followed by an attractive force to bring the opposite poles of the magnets back together.

If the device 10 is moved into a separated position (as shown in FIG. 13B, for example), the relative motion between portions 12, 14 may be minimally affected by the magnets 30, 22 and thus, the user may more freely spin the portions 12, 14. Thus, the device 10 provides two distinct spinning or twisting modes—a first mode which is detented in feel, and a second mode which is relatively smooth.

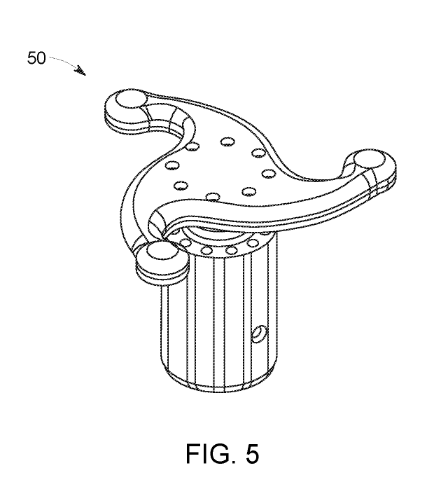

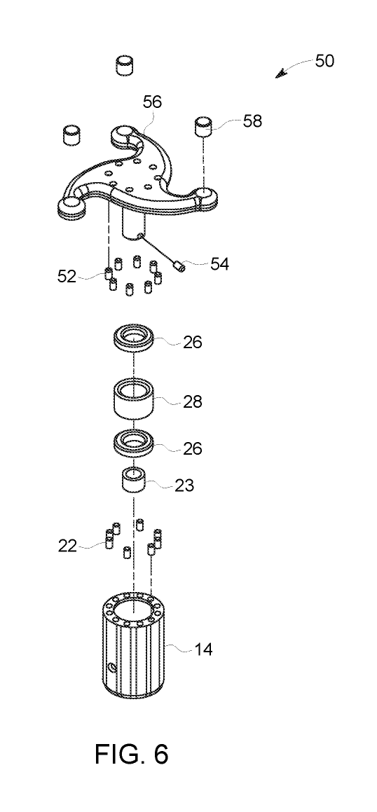

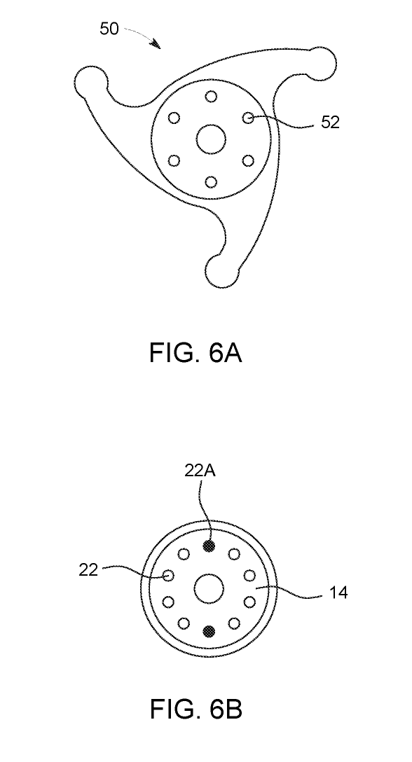

Referring now to FIGS. 5 through 6B, in some embodiments, the magnet portion 12 may be removed from the device 10 and replaced with a floating spinner 50. This would remove the toggle 16, 18 from the device 10 and add a different fidget feature for the user. The floating spinner 50 may include weights 58 that fit into ends of arms 56 of the floating spinner 50 to create angular momentum to maintain the floating spinner 50 in a spinning state upon user activation.

A plurality of spinner magnets 52 may be disposed on an underside of the floating spinner 50. The floating spinner 50 may include, for example, six spinner magnets 52. The magnets 52 may be equally spaced with pole symmetry. That is, all of the spinner magnets 52 may be oriented with their north pole or their south pole facing outward/downward and toward the bearing portion 14.

In some embodiments, the bearing portion 14 may include eight bearing portion magnets 22 equally spaced and disposed on its face. The bearing portion magnets 22 may have pole symmetry so that the poles of magnets 22 facing outward (toward the floating spinner 50) are the same as those of the spinner magnets 52. Thus, the magnets 22, 52 would repel each other when the device is assembled as shown in FIG. 5. The result is that the floating spinner 50 is floating at all times.

While individual magnets 22, 52 are shown as a plurality of individual magnets, these individual magnets may be replaced, in either the floating spinner 50, or the bearing portion 14, or both, with a single ring magnet.

In some embodiments, the bearing portion 14 can include eight equally spaced bearing portion magnets 22 with pole symmetry such as to repel the floating spinner magnets 52. The bearing portion 14 may further include two pole-symmetric, axially mirrored magnets 22A of opposite polar orientation to the other eight. The result is that the floating spinner 50 floats when rotational motion is present, but when rotational momentum is depleted, the two odd magnets 22A in the bearing portion 14 create a low-energy state where they attract the floating spinner magnets 52. This is possible because all repelling magnets are not in phase owing to the unequal circumferential distribution (six magnets 52 in the floating spinner and eight magnets 22 in the bearing end 14). The result is a two-state device—attraction or repulsion depending on rotational momentum.

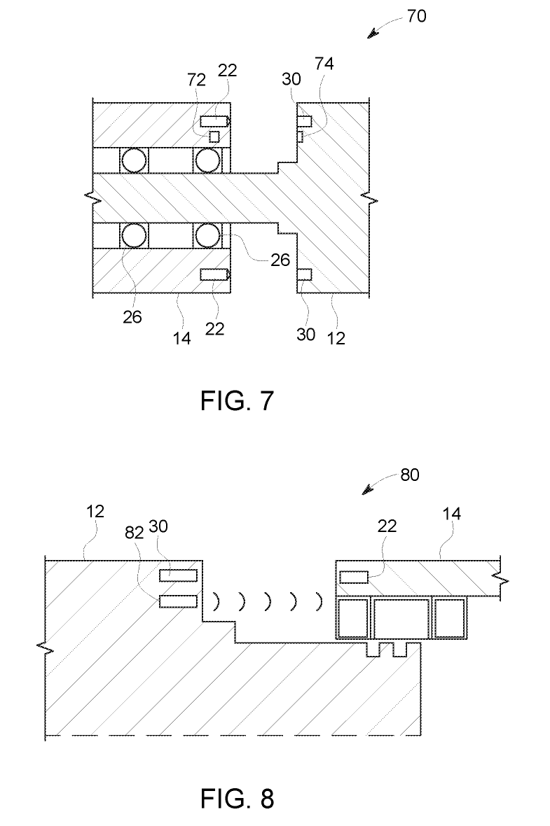

Referring to FIG. 7, in some embodiments, a device 70 can include a rotational position sensor, that may be based on a contact sensor or a non-contact sensor, between the magnet portion 12 and the bearing portion 14. In some embodiments, the rotational position sensor can include an optical sensor 72, or rotary transducer 72, disposed on one of the portions 12, 14 and a position indicator 74 disposed on the other one of the portions 12, 14. As shown in FIG. 7, the bearing portion 14 may include the optical sensor 72 and the magnet portion 12 may include the position indicator 74. In some embodiments, the position indicator 74 may be a Gray Code type disk, where a distinct pattern of high contrast markings may be used to determine absolute position of the magnet portion 12 relative to the bearing portion 14.

Referring to FIG. 8, in some embodiments, a device 80 can include a linear position sensor, that may be a hall type proximity or mechanical (reed switch) on the bearing portion 14 and the magnet portion 12. In some embodiments, the linear position sensor can include an optical linear position transducer 82 in either one of the bearing portion 14 or the magnet portion 12 (shown in FIG. 8 with the optical linear position transducer 82 in the magnet portion 12) to detect the distance to the other one of the portions 14, 12.

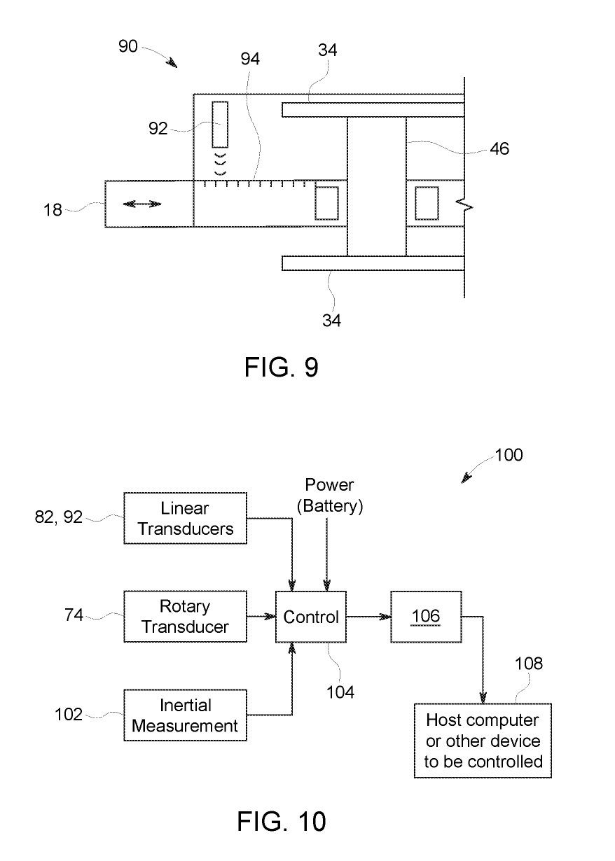

Referring to FIG. 9, in some embodiments, a device 90 can include a linear position sensor to determine the position of the toggle 18. In some embodiments, an optical Gray Code type linear transducer 92, or other absolute linear encoder, may be disposed within the magnet portion 12. The toggle 18 may include a linear Gray Code 94 or other type of indicator that may be detected by the transducer 92 to determine the position of the toggle 18. For both linear position sensors of FIGS. 8 and 9, binary or high precision linear position sensing could be used, depending on the specific application.

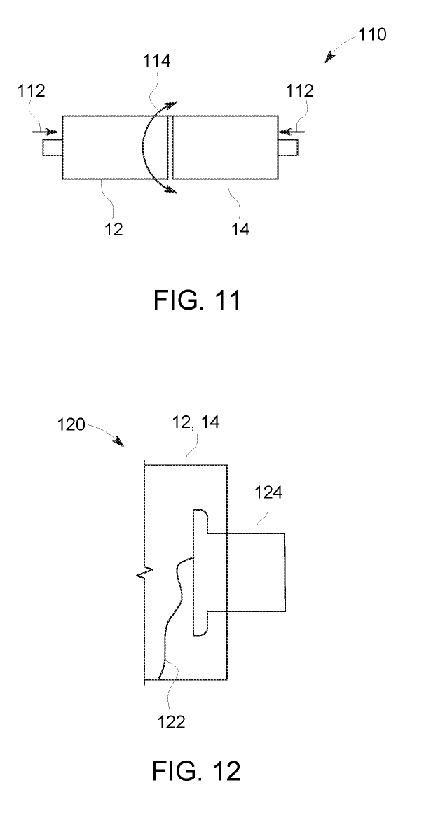

Referring to FIG. 10, the device may include a system 100 where the linear transducers 82, 92 as described in FIGS. 8 and 9 and the rotary transducer 74, as described in FIG. 7 may be send to a control 104 that may be powered by a power source, such as a battery, for example. Other measurements, such as inertial measurements via an inertial sensor 102 may also be sent to the control 104. Wireless module 106 may be used to send a wireless signal, such as a Bluetooth signal, out of the device to an external computing device 108, such as a host computer or other device to be controlled. FIGS. 11 through 18 may use the system 100, or a similar system, to permit the functionalities and external communications as described below.

As shown in FIG. 11, a device 110 with the system 100 of FIG. 10, rotation 114 of the magnet portion 12 relative to the bearing portion 14 may be used, for example, to cause the external computing device to scroll. Pressing the toggle as shown by arrows 112 may be received by the external computing device as a mouse click, for example. Thus, the device 110 may be used not only for fidgeting, but also as an input device for an external computing device.

Referring to FIG. 12, a device 120 may include, in either or both of the magnet portion 12 or the bearing portion 14, a push button 124 disposed on its ends in place of the toggle described above. The push button 124 may be, for example, a momentarily closed push button that does not mechanically extend through the device. The push button 124 may communicate a signal 122 to the control 104 (see FIG. 10), for example, to cause an external computing device to operate in a specific manner. For example, push buttons 124 may be disposed on each end of the device 120. The push buttons 124 may correlate to left and right mouse clicks.

The inertial sensor 102 (see FIG. 10) may be incorporated into the device 120 (or any of the devices described herein) to permit the automatic assignment of left and right mouse clicks, depending on the position of the device. Moreover, the inertial sensors, such as gyroscopes, accelerometers, magnetometers, or the like, may be useful to obtain gestures as inputs, where, for example, shaking the device may equate to an undo command, twirling the device may equate to a page advance command, shaking the device from side to side may equate to a command to change apps, or the like.

Referring to FIGS. 13A and 13B, in some embodiments, as discussed above, a rotational motion 130 when the device is in a closed state (FIG. 13A) may result in scrolling on an external computing device. A rotational motion 132 when the device is in an opened state (FIG. 13B) may result in a different command, such as a fast scroll, for example. While FIG. 8 shows two detents 13 that correlate to the open and closed states of FIGS. 13A and 13B, there may be multiple detents 13, permitting intermediate states, where rotation or toggling the toggle in each of these states may be equated into different commands on the external computing device.

In some embodiments, a microphone, as is known in the art, may be incorporated into the device. The microphone may permit the device to interact to an external computing device, a home automation device, or the like.

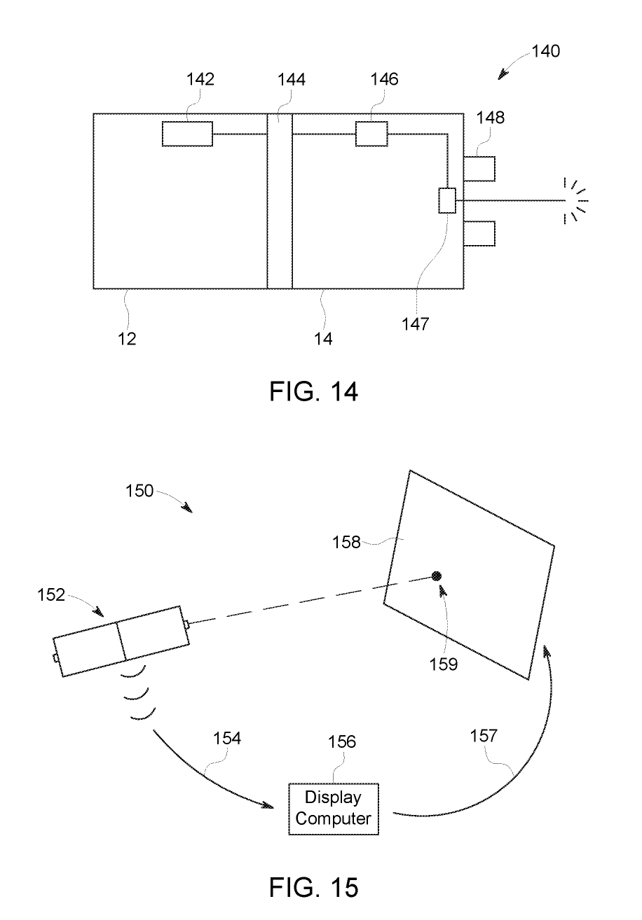

Referring to FIG. 14, in some embodiments, a device 14 may be used as a laser pointer. The device may include the magnet portion 12 and the bearing portion 14, as described above, with the addition of a slip ring 144 joining the portions 12, 14, a battery 142 and a switch 146 for toggling power from the battery 142 to a laser diode 147. In some embodiments, the laser diode 147 may send the laser through a button 148 having a central hole.

Referring to FIG. 15, in some embodiments, a system 150 can include a device 152, similar to device 10 described above, where the device 152 may be used to send a simulated laser dot or pointer 159 on a projector screen 158 based on a signal 154 received from the device 152 to the display computer 156. The display computer 156 may send a display signal 157 to the projector screen 158. Inertial measurements may be used in the device to move the pointer 159 on the projector screen 158.

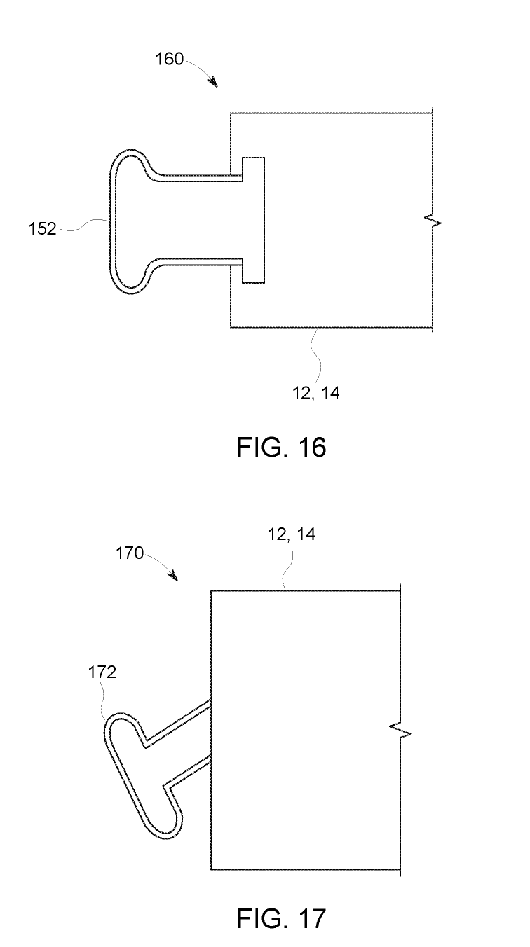

Referring to FIG. 16, in some embodiments, a non-compliant joystick device 160 may include a non-compliant joystick input 152 that may be disposed on one or both ends of the magnet portion 12 and the bearing portion 14. The joystick input 152 may include both x-y axis input as well as a z-axis “click” input. The joystick input 152 may be used to control an external computing device, as described above, control a game console, or the like.

Similarly, referring to FIG. 17, in some embodiments, a compliant joystick device 170 may include a compliant, proportional joystick 172 on one or both ends of the magnet portion 12 and the bearing portion 14. The joystick 172 may have functionality similar to those found in conventional game controllers, for example, and may be used to control an external computing device, as described above, control a game console, or the like.

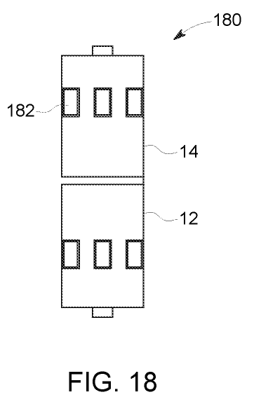

Referring to FIG. 18, in some embodiments, a multiple switch device 180 can have an exterior surface of one or both of the magnet portion 12 and the bearing portion 14 with a plurality of push buttons 182. The push buttons 182 may be mapped to various functions of an external computing device. For example, the various push buttons 182 may be mapped as left and right mouse clicks, as certain keystrokes, for scrolling, for controlling home automation, or the like.

In each of the embodiments of FIGS. 11 through 18, where the device may interact with an external computing device, the device may include a control mechanism to permit enabling or disenabling communication with the external communication device. For example, holding down a button for 5 seconds or a certain rotation pattern may be used to turn on or off external communications. In some embodiments, an indicator light (not shown) may be used to show whether external communications are activated.

While several different relative motion aspects are described above, other motions may be contemplated within the scope of the present invention. For example, the damping magnet 46 may be used to attract a cylindrical or spherical magnet moving about an exterior surface of the device. In some embodiments, the exterior surface can include flattened areas where the attraction between the outer movable magnet can have a greater attraction, due to the shorter distance, to the damping magnet 46. In other embodiments, the magnet portion may be used to move small spherical or cylindrical magnet or ferrous metal sphere or cylinder, herein simply referred to as a sphere, resting on a surface. For example, a user may encircle the magnet portion above the sphere resting on a surface, causing the sphere to mimic the motion of magnet portion. If the user gets too close, the sphere may be lifted up due to attraction to the damping magnet 46 and/or the magnet portion magnets 30.

All the features disclosed in this specification, including any accompanying abstract and drawings, may be replaced by alternative features serving the same, equivalent or similar purpose, unless expressly stated otherwise. Thus, unless expressly stated otherwise, each feature disclosed is one example only of a generic series of equivalent or similar features.

Claim elements and steps herein may have been numbered and/or lettered solely as an aid in readability and understanding. Any such numbering and lettering in itself is not intended to and should not be taken to indicate the ordering of elements and/or steps in the claims.

Many alterations and modifications may be made by those having ordinary skill in the art without departing from the spirit and scope of the invention. Therefore, it must be understood that the illustrated embodiments have been set forth only for the purposes of examples and that they should not be taken as limiting the invention as defined by the following claims. For example, notwithstanding the fact that the elements of a claim are set forth below in a certain combination, it must be expressly understood that the invention includes other combinations of fewer, more or different ones of the disclosed elements.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The claims are thus to be understood to include what is specifically illustrated and described above, what is conceptually equivalent, what can be obviously substituted and also what incorporates the essential idea of the invention.

What is claimed is:

1. A device comprising:
at least one of a spinning device and a toggle device, wherein
the spinning device comprises:
a first wheel having a first plurality of magnets disposed about an outer circumference of a first end;
a second wheel having a second plurality of magnets disposed about an outer circumference of a first end, the first end of the first wheel disposed adjacent against the first end of the second wheel, the first and second wheels independently rotatable about the longitudinal axis of the spinning device; and
the toggle device comprises:
a toggle mechanism extending along the longitudinal axis of the spinning device, the toggle mechanism movable between a first position, with a visible portion of the toggle mechanism being visible out of a second end of the first wheel, and a second position, with the visible portion of the toggle mechanism being visible out of a second end of the second wheel.

2. The device of claim 1, wherein:
the first plurality of magnets is arranged with poles facing one of parallel to and perpendicular with a longitudinal axis of the spinning device
the second plurality of magnets is arranged with poles facing one of parallel to and perpendicular with the longitudinal axis of the spinning device.

3. The device of claim 1, wherein the first wheel is a magnet portion and the second wheel is a bearing portion.

4. The device of claim 3, wherein the bearing portion includes at least one bearing disposed therein.

5. The device of claim 3, wherein the magnet portion includes a conductive metal tube having a magnet disposed therein, the magnet portion further comprising a toggle member extending from the second end of the magnet portion and attached to a first side of the magnet, the toggle member further attached to a second side of the magnet and extending outward from the first end of the magnet portion, into the first end of the bearing portion.

6. The device of claim 3, wherein the magnet portion includes an extending portion extending from the first end thereof, the extending portion fitting into the one or more bearings in the bearing portion.

7. The device of claim 6, wherein the extending portion includes at least two detents formed therein and the bearing portion includes at least one retention member engaging one of the at least two detents to hold the magnet portion and bearing portion in at least one of a first position and a second position, where, in the first position, the magnet portion and the bearing portion are adjacent each other and, in the second position, the magnet portion is separated from the bearing portion by a space.

8. The device of claim 1, further comprising at least one rotational position sensor operable to detect a relative rotational position of the first wheel relative to the second wheel.

9. The device of claim 1, further comprising at least one linear position sensor operable to detect a distance between the first end of the first wheel and the first end of the second wheel.

10. The device of claim 1, further comprising at least one linear position sensor operable to detect a position of the toggle mechanism.

11. The device of claim 1, further comprising a controller receiving inputs from one or more position sensors disposed in the spinning device.

12. The device of claim 10, further comprising a wireless communication module for sending signals from the controller to an external computing device.

13. The device of claim 1, further comprising a laser diode configured to emit a laser signal from the spinning device.

14. The device of claim 1, further comprising a plurality of push buttons disposed about an external surface of at least one of the first wheel and the second wheel.

15. A spinning device comprising:
a first wheel having a first plurality of magnets disposed about an outer circumference of a first end, the first plurality of magnets arranged with poles facing parallel to a longitudinal axis of the spinning device;
a second wheel having a second plurality of magnets disposed about an outer circumference of a first end, the second plurality of magnets arranged with poles facing parallel to a longitudinal axis of the spinning device, the first end of the first wheel disposed adjacent against the first end of the second wheel, the first and second wheels independently rotatable about the longitudinal axis of the spinning device; and
an input device extending from at least one of the second end of the first wheel and the second end of the second wheel.

16. The spinning device of claim 15, wherein the input device is a push button.

17. The spinning device of claim 15, wherein the input device is one of a compliant and a non-compliant joystick input device.

18. The spinning device of claim 15, further comprising:
a controller receiving inputs from the input device; and
a wireless communication module for sending signals from the controller to an external computing device.

19. A spinning device comprising:
a first wheel having a first number of magnets disposed about an outer circumference of a first end, the first plurality of magnets arranged with like poles facing parallel to a longitudinal axis of the spinning device;
a floating spinner having a second number of magnets disposed about a bottom surface thereof, the second number of magnets arranged with like poles facing downward and parallel to a longitudinal axis of the spinning device, the floating spinner fitting partially in the first wheel, the floating spinner being independently rotatable about the longitudinal axis of the spinning device, wherein
the magnets of the first wheel repel the magnets of the floating spinner.

20. The spinning device of claim 19, wherein the first number of magnets is different from the second number of magnets.

21. The spinning device of claim 20, further comprising two pole symmetric, axially mirrored magnets disposed on one of the first wheel and the floating spinner, the two pole symmetric axially mirrored magnets having an opposite pole to permit magnetic attraction between the first wheel and the floating spinner.
